(19) United States
(12) Patent Application Publication
(10) Pub. No.: US 2023/0077336 A1
(43) Pub. Date: Mar. 16, 2023

(54) METHOD FOR MANUFACTURING CONDUCTING PATH IN DOPED REGION, TRENCH-TYPE MOSFET DEVICE AND MANUFACTURING METHOD THEREOF

(71) Applicant: Hangzhou Silicon-Magic Semiconductor Technology Co., Ltd., Hangzhou City (CN)

(72) Inventors: Jian Liu, Los Angeles, CA (US); Jinyong Cai, Hangzhou City (CN)

(21) Appl. No.: 17/944,284

(22) Filed: Sep. 14, 2022

(30) Foreign Application Priority Data
Sep. 15, 2021 (CN) 202111078843.X

(51) Int. Cl. H01L 29/417; H01L 29/40; H01L 29/78; H01L 29/66

(52) U.S. Cl. CPC H01L 29/41741; H01L 29/407; H01L 29/7813; H01L 29/66727; H01L 29/66734

(57) ABSTRACT

Disclosed is a method for manufacturing a conducting path in a doped region, comprising: forming a dielectric layer on a semiconductor layer which includes the doped region; forming an opening in the dielectric layer; forming a side wall on sidewall of the opening; etching the semiconductor layer through the opening to form a conduction hole extending to the doped region; filling the conduction hole with conductive material to form a conducting path, wherein the side wall reduces a transverse dimension of the conducting path. According to the method for manufacturing the conducting path in the doped region in the present disclosure, by forming the side wall on sidewall of the opening in the dielectric layer, the transverse dimension of the opening in the dielectric layer is reduced, thereby the semiconductor layer is etched with a narrower opening to obtain the conduction hole with a smaller size, device performance is improved.

### CROSS-REFERENCE TO RELATED APPLICATIONS

The present application claims the priority to Chinese Patent Application No. 202111078843.X, filed on Sep. 15, 2021, entitled by “METHOD FOR MANUFACTURING CONDUCTING PATH IN DOPED REGION, TRENCH-TYPE MOSFET DEVICE AND MANUFACTURING METHOD THEREOF”, and published as CN113782429A on Dec. 10, 2021, the disclosures of which are incorporated herein by reference in their entireties.

### FIELD OF TECHNOLOGY

The present disclosure relates to a technical field of semiconductor manufacturing, in particular to a method for manufacturing a conducting path in a doped region, a trench-type MOSFET device and a manufacturing method of a trench-type MOSFET device.

### BACKGROUND

Power semiconductor devices, also known as power electronic devices, include power diodes, thyristors, VDMOS (Vertical Double Diffused Metal Oxide Semiconductor) field effect transistors, LDMOS (Lateral Diffused Metal Oxide Semiconductor) field effect transistors and IGBTs (Insulated Gate Bipolar Transistors). A VDMOS field effect transistor includes a source region and a drain region formed on opposite surfaces of a semiconductor substrate, and when the VDMOS field effect transistor is operated in an on state, current flows mainly along a longitudinal direction of the semiconductor substrate.

Based on the VDMOS field effect transistor, a trench-type MOSFET is further developed. As shown in FIG. 1, the trench-type MOSFET comprises a substrate 110, an epitaxial layer 120, an insulating layer 131, a first gate conductor 132, a gate oxide layer 133, a second gate conductor 134, a dielectric layer 135, a body region 121, a source region 122, a contact region 123, a first conductive layer 141 and 142, and a second conductive layer 143. However, with size reduction of a cell region in the trench-type MOSFET, a transverse dimension of a CONT (lead) hole (e.g., the first conductive layer 141 as shown in FIG. 1) also accounts for an increasing proportion of the size of the cell region. In order to ensure enough design window, performance of the designed device may be poor, so it is necessary to reduce the size of CONT hole, however, a smaller size of the CONT hole requires a better manufacturing equipment, which increases process cost.

### SUMMARY

In view of the above problems, an objective of the present disclosure is to provide a method for manufacturing a conducting path in a doped region, wherein by forming a side wall on sidewall of an opening in a dielectric layer, a transverse dimension of the opening in the dielectric layer is reduced, so that the semiconductor layer can be etched through a narrower opening, a conduction hole and a conducting path with smaller transverse dimensions can be finally obtained, respectively, thus improving device performance

According to a first aspect of the present disclosure, there is provided a method for manufacturing a conducting path in a doped region, wherein the method comprises: forming a dielectric layer on a semiconductor layer, which includes the doped region; forming an opening in the dielectric layer; forming a side wall on sidewall of the opening; etching the semiconductor layer through the opening to form a conduction hole extending to the doped region; and filling the conduction hole with conductive material to form the conducting path, wherein the side wall is used for reducing a transverse dimension of the conducting path.

In some embodiments, step of forming a side wall on sidewall of the opening comprises: forming a barrier layer on a surface of the dielectric layer and in the opening; removing a portion, which is located on the surface of the dielectric layer, of the barrier layer, and a portion, which is located at bottom of the opening, of the barrier layer, wherein the side wall is formed by a portion, which is located on sidewall of the opening, of the barrier layer.

In some embodiments, step of forming the opening in the dielectric layer comprises: forming a patterned mask layer on the dielectric layer; forming the opening by transferring a pattern of the mask layer to the dielectric layer through the mask layer.

According to a second aspect of the present disclosure, there is provided a manufacturing method of a trench-type MOSFET device, wherein the manufacturing method comprises: forming an epitaxial layer on a semiconductor substrate; forming a trench structure, a body region and a source region in the epitaxial layer, wherein the body region is in contact with the trench structure, and the source region is located in the body region; forming a dielectric layer on a surface of the epitaxial layer; forming an opening in the dielectric layer; forming a side wall on sidewall of the opening; etching the epitaxial layer through the opening to form a conduction hole extending to the body region; and filling the conduction hole with conductive material to form a conducting path, wherein the sidewall is used for reducing a transverse dimension of the conducting path.

In some embodiments, a cell region of the trench-type MOSFET device is a region surrounded by an outer periphery of the body region, and the conducting path is in contact with the outer periphery of the body region.

In some embodiments, step of forming the sidewall on sidewall of the opening comprises: forming a barrier layer on a surface of the dielectric layer and in the opening; removing a portion, which is located on the surface of the dielectric layer, of the barrier layer, and a portion, which is located at bottom of the opening, of the barrier layer, wherein the side wall is formed by a portion, which is located on sidewall of the opening, of the barrier layer.

In some embodiments, the trench structure comprises: a trench located in the epitaxial layer; a first gate conductor, a gate oxide layer, a second gate conductor and an insulating layer in the trench, the insulating layer covers around sidewall of the trench and the first gate conductor is surrounded by the insulating layer, the gate oxide layer is located on an upper-part sidewall of the trench, and the second gate conductor is located on a portion, which is located in an upper part of the trench, of the insulating layer.

In some embodiments, after step of filling the conduction hole with conductive material to form the conducting path, the manufacturing method further comprises: forming a second conductive layer on a second surface of the semiconductor substrate.

According to a third aspect of the present disclosure, there is provided a trench-type MOSFET device formed by using the manufacturing method of the trench-type MOSFET device as described above.

According to the method for manufacturing the conducting path in the doped region provided by the present disclosure, the side wall is formed on sidewall of the opening in the dielectric layer, thus reducing the transverse dimension of the opening in the dielectric layer, so that the semiconductor layer can be etched through a narrower opening, and the conduction hole and the conducting path can be finally obtained with smaller transverse dimensions, respectively, which reduces an influence caused by the size of the conduction hole when the size of the device is reduced, thus device performance can be improved, and at the same time, further size reduction on some devices can be achieved.

According to the trench-type MOSFET device and the manufacturing method thereof provided by the present disclosure, the method for manufacturing the conducting path in the doped region is used, thus reducing the transverse dimensions of the conducting path and the conduction hole in the source region, respectively, so that in a device comprising a cell region with smaller and smaller size, an influence, which is caused by the conducting path, on a channel of the device can be reduced, and device performance can be improved.

### BRIEF DESCRIPTION OF THE DRAWINGS

The above and other objects, features and advantages of the present disclosure will become more apparent from the following description of embodiments of the present disclosure with reference to the accompanying drawings, in which:

FIG. 1 shows a schematic structural diagram of a conducting path according to the prior art;

FIG. 2 shows a schematic structural diagram of a conducting path according to an embodiment of the present disclosure;

FIGS. 3a to 3f show cross-sectional views corresponding to stages of a method for manufacturing a conducting path according to an embodiment of the present disclosure;

FIG. 4 shows a schematic structural diagram of a trench-type MOSFET device according to an embodiment of the present disclosure.

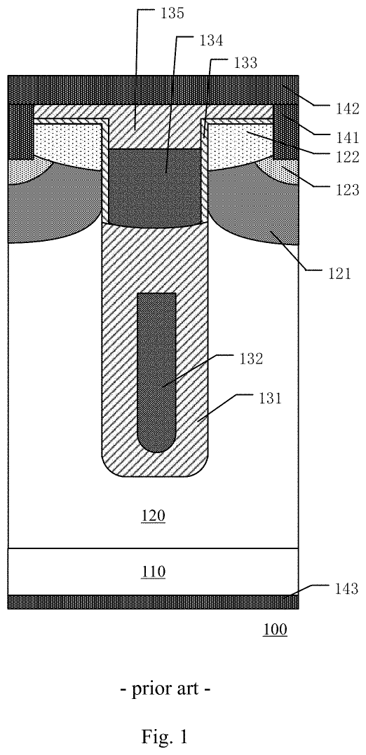

### DETAILED DESCRIPTION OF THE EMBODIMENTS

Various embodiments of the present disclosure will be described in more detail below with reference to the accompanying drawings. Throughout the various figures, like elements are denoted by the same or similar reference numerals. For the sake of clarity, various parts in the drawings are not drawn to scale. In addition, some well-known parts may not be shown. For the sake of simplicity, the semiconductor structure after several steps may be described in one diagram.

It should be understood that, when describing a structure of a device, in a case that one layer or one region is referred to as being located “on” or “above” another layer or another region, it means the one layer or the one region is located above another layer or another region, with or without additional layers or additional regions therebetween. Moreover, in a case that the device is turned upside down, the one layer or the one region will be “under” or “below” another layer or another region.

In a case that the one layer or the one region is located directly on another layer or another region, the expression will be “A is located directly on B”, “A is located above and adjacent to B”, “A is located above and contacts with B” or “A is located on an upper surface of B”.

Specific embodiments of the present disclosure are described in further detail below, with reference to the accompanying drawings and the corresponding embodiments.

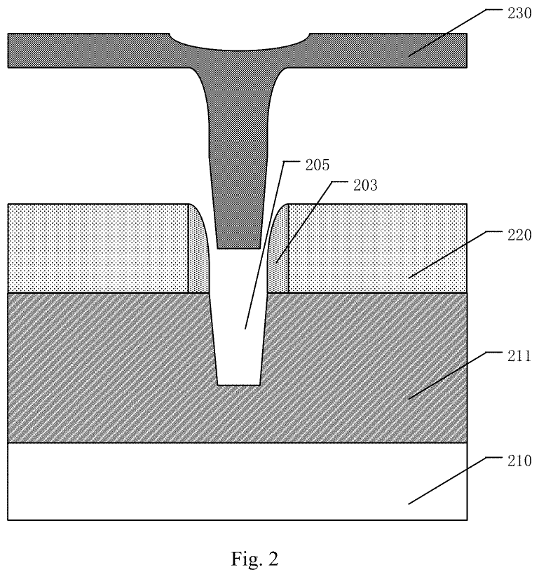

FIG. 2 shows a schematic structural diagram of a conducting path according to an embodiment of the present disclosure. The schematic structural diagram of the conducting path is, for example, a schematic diagram of a structure of a conducting path of an electrode leading from the source region in the trench-type MOSFET device.

Referring to the schematic structural diagram as shown in FIG. 2, according to the present disclosure, a semiconductor layer 210, a dielectric layer 220 and a conducting path 230 is included. A doped region 211 is comprised in the semiconductor layer 210. The dielectric layer 220 has an opening used for limiting a transverse dimension of a conduction hole 205. The conduction hole 205 is formed in the semiconductor layer 210 and extends into the doped region 211 in the semiconductor layer 210. On sidewall of the opening of the dielectric layer 220, a side wall 203 is formed, which reduces a transverse dimension of the opening in the dielectric layer 220.

In this embodiment, when the semiconductor layer 210 is etched through the narrowed opening in the dielectric layer 220, the transverse dimension of the formed conduction hole 205 can be reduced, thereby reducing an influence, which is caused by the conduction hole 205 and the conducting path 230 in the conduction hole 205, on other structures (not shown in the figure) in the semiconductor layer 210, so that yield and reliability of the device can be improved.

In some other embodiments, the semiconductor layer 210, for example, has no doped region 211, the dielectric layer 220 is, for example, a hard mask layer, and after the conducting path 230 is formed by filling the conduction hole 205 in the semiconductor layer 210. The dielectric layer 220 and a portion, which is located on the dielectric layer 220, of the conducting path 230 can be removed, so that a conducting path structure with reduced transverse dimension can also be obtained.

In a specific device structure, such as a trench-type MOSFET device, the semiconductor layer 210 is, for example, an epitaxial layer or a gate conductor layer, the dielectric layer 220 is, for example, an interlayer dielectric layer on the epitaxial layer, the doped region 211 is, for example, a body region, and the conducting path 230 is, for example, an electrode structure leading from a source region or a gate structure.

In another specific device structure, such as a memory device requiring bonding, the semiconductor layer 210 is, for example, a bonding layer, the dielectric layer 220 is, for example, a mask layer, and the conducting path 230 is, for example, a metal conducting path for improving bonding performance of the bonding layer, i.e., the dielectric layer 220 which is used as a mask layer and the conducting path above the dielectric layer 220 are removed in a subsequent step.

Therefore, the present disclosure illustrates an exemplary method for reducing the transverse dimension of the conducting path, that is, by forming the side wall 203 on sidewall of the opening which defines the transverse dimension of the conduction hole and is located in the dielectric layer 220, the transverse dimension of the opening can be reduced, thus the transverse dimension of the conduction hole formed by etching through the opening can also be smaller than an initial transverse dimension of the opening. In case that the transverse dimension of the opening is set to be as small as possible, the method for manufacturing the conducting path can further reduce the transverse dimension of the opening, thereby reducing the influence, which is caused by the conducting path, on the device structure and providing a method for further miniaturizing the device.

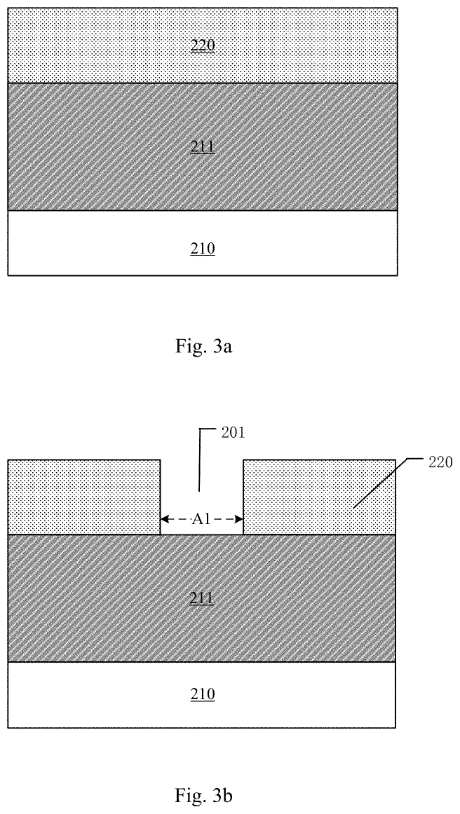

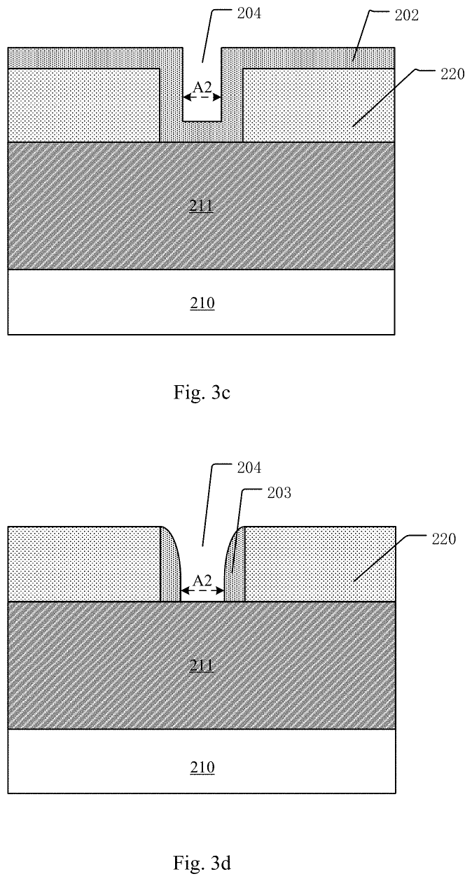

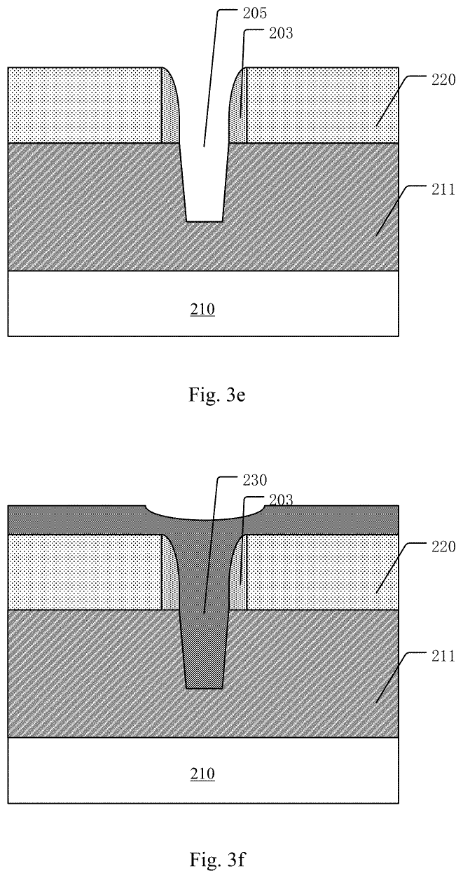

FIGS. 3a to 3f show cross-sectional views corresponding to various stages of the method for manufacturing the conducting path according to an embodiment of the present disclosure. The conducting path located in the epitaxial layer of the trench-type MOSFET device is taken as an example and is described in detail.

Step 1: A dielectric layer 220 is formed on a first surface of the semiconductor layer 210 and an opening 201 is formed in the dielectric layer 220, as shown in FIGS. 3a and 3b.

In this step, the dielectric layer 220 is formed on the first surface of the semiconductor layer 210 by performing a process such as chemical vapor deposition process or physical vapor deposition process. The dielectric layer 220 is then patterned to form an opening 201 in the dielectric layer 220.

In this embodiment, a side, which is adjacent to the first surface, of the semiconductor layer 210 comprises a doped region 211, the semiconductor layer 210 is, for example, an epitaxial layer formed of N-type doped silicon material, and the dielectric layer 220 is formed of insulating material, such as silicon oxide or silicon nitride.

A method for forming the opening 201 in the dielectric layer 220 comprises, for example, forming a mask layer or a photoresist layer on a surface of the dielectric layer 220, patterning the mask layer or the photoresist layer, and etching the dielectric layer 220 via the patterned mask layer or the patterned photoresist layer to form the opening 201. The opening 201 is configured to penetrate the dielectric layer 220 so as to expose the surface of the semiconductor layer 210.

The transverse dimension A1 of the opening 201 formed in this step may be larger than a predetermined transverse dimension D of the opening, however, through etching process, the transverse dimension A1 of the opening 201 cannot be further reduced to match the predetermined value D.

In such an embodiment of the trench-type MOSFET device, the dielectric layer 220 is positioned as an insulating layer on the surface of the semiconductor layer 210.

Step 2: A barrier layer 202 is formed on the surface of the dielectric layer 220, as shown in FIG. 3c.

In this step, the barrier layer 202 is formed on the surface of the dielectric layer 220 by performing an atomic layer deposition process, a chemical vapor deposition process, or a physical vapor deposition process, and at the same time, a conformal layer is also formed by the barrier layer 202 on sidewall and bottom of the opening 201 in the dielectric layer 220, so that the transverse dimension of the opening 204 is reduced.

In this embodiment, material of the barrier layer 202 is, for example, TEOS (tetraethoxysilane). The barrier layer 202 is formed along sidewall and bottom of the opening such that a distance between two opposite sidewalls in the opening 204 changes from a distance A1 between inner sidewalls of the dielectric layer 220 into a distance A2 between inner sidewalls of the barrier layer 202, and A2 is significantly less than A1, so that the transverse dimension of the opening 204 in the dielectric layer 220 is reduced.

Step 3: A portion, which is located on the surface of the dielectric layer 220, of the barrier layer 202, and a portion, which is located on the semiconductor layer 210 and exposed by the opening 204, of the barrier layer 202 are removed, and only a portion, which is located on sidewall of the opening 204 in the dielectric layer 220, of the barrier layer 202 is remained to form the side wall 203, as shown in FIG. 3d.

In this step, for example, the portion, which is located on the surface of the dielectric layer 220, of the barrier layer 202 is removed by performing a chemical mechanical grinding process, and then the portion, which is located at the bottom of the opening 201, of the barrier layer 202 is removed by performing an anisotropic dry etching process, only the portion, which is located on sidewall of the opening 204, of the barrier layer 202 is remained to form the side wall 203. In this embodiment, the dry etching process comprises, for example, an etching process such as an ion etching process, a milling ion etching process, etc.

When the portion, which is located at bottom of the opening 204, of the barrier layer 202 is being removed, the portion, which is located on the surface of the dielectric layer 220 and in the opening 204, of the barrier layer 202 can may also be etched, thereby enlarging a size of a top part of the opening 204 and facilitating material filling during a subsequent process of material deposition.

In this step, by controlling a deposited thickness of the barrier layer 202, a thickness of the side wall 203 can be controlled so that the transverse dimension A2, which is reduced through the side wall 203, of the opening 204 may match the predetermined width value D.

Step 4: A conduction hole 205 extending to the doped region 211 is formed in the semiconductor layer 210 via the dielectric layer 220 and the side wall 203, as shown in FIG. 3e.

In this step, the semiconductor layer 210 is etched via the opening 204 in the dielectric layer 220 by performing an anisotropic dry etching process, thereby forming the conduction hole 205 in the semiconductor layer 210, bottom of the conduction hole 205 is located in the doped region 211.

In this embodiment, since the side wall 203 is formed on sidewall of the opening 204 in the dielectric layer 220, the transverse dimension A2 of the opening 204 in the dielectric layer 220 is reduced compared to A1, and the transverse dimension of the conduction hole 205 formed by etching the semiconductor layer 210 through the opening 204 in the dielectric layer 220 can also be reduced, for example, the transverse dimension of the conduction hole 205 is not greater than A2.

Step 5: A conducting path 230 is formed on the surface of the dielectric layer 220, and also fills the conduction hole 205, as shown in FIG. 3f.

In this step, the conduction hole 205 is filled with conductive material and the conducting path 230 is formed on the surface of the dielectric layer 220 and in the conduction hole 205. The material of the conducting path 230 is, for example, a metal material.

In this step, since the transverse dimension of the top part of the opening 204 is larger (than a bottom part of the opening 204), it can avoid blockage in the top part of the opening during the process of material filling.

In the above-described embodiment, a method for reducing the transverse dimension of the conducting path is described by taking the electrode leading from the source region in the trench-type MOSFET device as an example. In some other device structures, the method for manufacturing the conducting path shown in the present disclosure can also be used to reduce the transverse dimension of the conducting path.

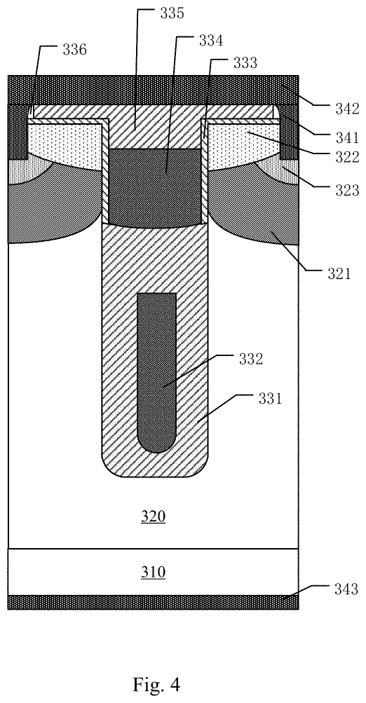

FIG. 4 shows a schematic structural diagram of a trench-type MOSFET device according to an embodiment of the present disclosure.

Referring to FIG. 4, an epitaxial layer 320 is formed on a first surface of a substrate 310, and a trench structure is formed in the epitaxial layer 320. The step of forming the trench structure in the epitaxial layer comprises: forming a trench in the epitaxial layer 320, forming a first gate conductor 332, a gate oxide layer 333, a second gate conductor 334 and an insulating layer 331 in the trench, and forming a body region 321 and a source region 322 in the epitaxial layer 320. Further, a dielectric layer 335 is formed on a surface of a front-end device, that is, a surface of the epitaxial layer 320, then an opening is formed in the dielectric layer 335, a side wall 336 is formed on sidewall of the opening, the epitaxial layer 320 is etched through the opening to form a conduction hole, and then metal material is deposited to form a conducting layer 342, wherein the conducting layer 342 fills the opening extending in the dielectric layer 335 and the epitaxial layer 320 to form a conducting path 341. Further, a contact layer 323 is formed in the epitaxial layer 320 via the conduction hole and a second conductive layer 343 is formed on a second surface of the substrate 310.

In the trench-type MOSFET device shown in FIG. 4, since the method for reducing the transverse dimension of the conducting path is adopted, the transverse dimension of the conducting path 341, which is finally formed, is also reduced, thereby reducing the influence, which is caused by the conducting path 341, on the second gate conductor 334 in the trench and providing an idea for further reducing a size of an overall structure of the device.

According to the method for manufacturing the conducting path in the doped region provided by the present disclosure, the side wall is formed on sidewall of the opening in the dielectric layer, thus reducing the transverse dimension of the opening in the dielectric layer, so that the semiconductor layer can be etched through a narrower opening, and the conduction hole and the conducting path can be finally obtained with smaller transverse dimensions, respectively, which reduces an influence caused by the size of the conduction hole when the size of the device is reduced, thus device performance can be improved, and at the same time, further size reduction on some devices can be achieved.

According to the trench-type MOSFET device and the manufacturing method thereof provided by the present disclosure, the method for manufacturing the conducting path in the doped region is used, thus reducing the transverse dimensions of the conducting path and the conduction hole in the source region, respectively, so that in a device comprising a cell region with smaller and smaller size, an influence, which is caused by the conducting path, on a channel of the device can be reduced, and device performance can be improved.

The embodiments according to the present disclosure are described above, but the embodiments do not exhaust all the details and do not limit the invention to only the specific embodiments described. Obviously, according to the above description, many modifications and changes can be made. These embodiments are selected and specifically described in this specification in order to better explain the principles and practical disclosures of the present disclosure, thereby enabling those skilled in the art to make good use of the present disclosure and modifications based on the present disclosure. The present disclosure is limited only by the claims and their full scope and equivalents.

What is claimed is:

1. A method for manufacturing a conducting path in a doped region, comprising:
forming a dielectric layer on a semiconductor layer, which includes the doped region;
forming an opening in the dielectric layer;
forming a side wall on sidewall of the opening;
etching the semiconductor layer through the opening to form a conduction hole extending to the doped region; and
filling the conduction hole with conductive material to form the conducting path,
wherein, the side wall is used for reducing a transverse dimension of the conducting path.

2. The method according to claim 1, wherein step of forming the side wall on sidewall of the opening comprises:
forming a barrier layer on a surface of the dielectric layer and in the opening;
removing a portion, which is located on the surface of the dielectric layer, of the barrier layer and a portion, which is located at bottom of the opening, of the barrier layer, wherein the side wall is formed by a portion, which is located on sidewall of the opening, of the barrier layer.

3. The method according to claim 1, wherein step of forming the opening in the dielectric layer comprises:
forming a patterned mask layer on the dielectric layer;
forming the opening by transferring a pattern of the mask layer to the dielectric layer through the mask layer.

4. A manufacturing method of a trench-type MOSFET device, comprising:
forming an epitaxial layer on a first surface of a semiconductor substrate;
forming a trench structure, a body region and a source region in the epitaxial layer, wherein the body region is in contact with the trench structure, and the source region is located in the body region;
forming a dielectric layer on a surface of the epitaxial layer;
forming an opening in the dielectric layer;
forming a side wall on sidewall of the opening;
etching the epitaxial layer through the opening to form a conduction hole extending to the body region; and
filling the conduction hole with conductive material to form a conducting path,
wherein the side wall is used for reducing a transverse dimension of the conducting path.

5. The manufacturing method according to claim 4, wherein a cell region of the trench-type MOSFET device is a region surrounded by an outer periphery of the body region, and the conducting path is in contact with the outer periphery of the body region.

6. The manufacturing method according to claim 5, wherein step of forming the side wall on sidewall of the opening comprises:
forming a barrier layer on a surface of the dielectric layer and in the opening;
removing a portion, which is located on the surface of the dielectric layer, of the barrier layer, and a portion, which is located at bottom of the opening, of the barrier layer, wherein the side wall is formed by a portion, which is located on sidewall of the opening, of the barrier layer.

7. The manufacturing method according to claim 5, wherein the trench structure comprises: a trench located in the epitaxial layer; a first gate conductor, a gate oxide layer, a second gate conductor and an insulating layer in the trench, the insulating layer covers around sidewall of the trench and the first gate conductor is surrounded by the insulating layer, the gate oxide layer is located on an upper-part sidewall of the trench, and the second gate conductor is located on a portion, which is located in an upper part of the trench, of the insulating layer.

8. The manufacturing method according to claim 5, wherein after step of filling the conduction hole with conductive material to form the conducting path, the manufacturing method further comprises: forming a second conductive layer on a second surface of the semiconductor substrate.

9. A trench-type MOSFET device, comprising:
an epitaxial layer located on a first surface of a semiconductor substrate;
a trench structure, a body region and a source region located in the epitaxial layer, wherein the body region is disposed adjacent to the trench structure, and the source region is located in the body region;
a dielectric layer located on a surface of the epitaxial layer;
a conducting path extending through the dielectric layer to the body region,
wherein a side wall, which is used for forming a conduction hole extending to the body region and reducing a transverse dimension of the conducting path, is located between the conducting path and the dielectric layer, wherein the conducting path is located in the conduction hole.

10. The trench-type MOSFET device according to claim 9, wherein a cell region of the trench-type MOSFET device is a region surrounded by an outer periphery of the body region, and the conducting path is in contact with the outer periphery of the body region.

11. The trench-type MOSFET device according to claim 10, wherein the trench structure comprises: a trench located in the epitaxial layer; a first gate conductor, a gate oxide layer, a second gate conductor and an insulating layer in the trench, the insulating layer covers around sidewall of the trench and the first gate conductor is surrounded by the insulating layer, the gate oxide layer is located on an upper-part sidewall of the trench, and the second gate conductor is located on a portion, which is located in an upper part of the trench, of the insulating layer.

12. The trench-type MOSFET device according to claim 10, further comprising: a second conductive layer on a second surface, which is opposite to the first surface, of the semiconductor substrate.
